(19) United States
(12) Patent Application Publication
(10) Pub. No.: US 2023/0331633 A1
(43) Pub. Date: Oct. 19, 2023

(54) SPARK PLASMA SINTERED COMPONENT FOR PLASMA PROCESSING CHAMBER

(71) Applicant: Lam Research Corporation, Fremont, CA (US)

(72) Inventors: Lin XU, Fremont, CA (US); Harmeet SINGH, Fremont, CA (US); Pankaj HAZARIKA, Sherwood, OR (US); Satish SRINIVASAN, Newark, CA (US); Robin KOSHY, Fremont, CA (US)

(21) Appl. No.: 18/247,724

(22) PCT Filed: Nov. 3, 2021
(86) PCT No.: PCT/US2021/057926

§ 371 Date: Apr. 3, 2023

Related U.S. Application Data
(60) Provisional application No. 63/110,212, filed on Nov. 5, 2020.

(51) Int. Cl. C04B 35/565; H01J 37/32; C04B 35/64

(52) U.S. Cl. CPC C04B 35/565; H01J 37/32642; H01J 37/3244; C04B 35/64; H01J 2237/334; C04B 2235/3826; C04B 2235/3821; C04B 2235/612; C04B 2235/666; C04B 2235/9669

(57) ABSTRACT

A method for making a component for use in a plasma processing chamber is provided. A non-oxide silicon containing powder composition is placed in a mold, wherein the non-oxide silicon containing powder composition consists essentially of a non-oxide silicon containing powder and at least one of a B or B4C dopant. The non-oxide silicon containing powder composition is subjected to spark plasma sintering (SPS) to form a spark plasma sintered component. The spark plasma sintered component is machined into a plasma processing chamber component.

### CROSS-REFERENCE TO RELATED APPLICATION

This application claims the benefit of priority of U.S. Application No. 63/110,212, filed Nov. 5, 2020, which is incorporated herein by reference for all purposes.

### BACKGROUND

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

The disclosure relates to parts for use in a plasma processing chamber. More specifically, the disclosure relates to dielectric, plasma exposed parts in a plasma processing chamber.

In forming semiconductor devices, plasma processing chambers are used to process the substrates. Some plasma processing chambers have dielectric parts, such as liners, gas distribution plates, and edge rings.

For some of the dielectric parts for plasma processing chambers, silicon carbide (SiC) has been widely used due to the high etch resistance of SiC. The technique to produce a SiC edge ring is predominantly through a chemical vapor deposition (CVD) method where a thick SiC coating is grown onto a graphite mandrel. After the removal of the graphite mandrel, the CVD-produced SiC blank is then machined into an edge ring. With more aggressive plasma chemistries and more stringent demand in a part lifetime, CVD-produced pure SiC cannot meet lifetime requirements.

### SUMMARY

To achieve the foregoing and in accordance with the purpose of the present disclosure, a method for making a component for use in a plasma processing chamber is provided. A non-oxide silicon containing powder composition is placed in a mold, wherein the non-oxide silicon containing powder composition consists essentially of a non-oxide silicon containing powder and at least one of a B or B₄C dopant. The non-oxide silicon containing powder composition is subjected to spark plasma sintering (SPS) to form a spark plasma sintered component. The spark plasma sintered component is machined into a plasma processing chamber component.

In another manifestation, an apparatus for processing a wafer is provided. A plasma processing chamber is provided. A wafer support for supports a wafer within the plasma processing chamber. A gas source for provides gas to the plasma processing chamber. A component comprises a spark plasma sintered body comprising a non-oxide material containing silicon consisting essentially of a non-oxide silicon containing material and at least one of a B or B₄C dopant.

In another manifestation, a showerhead for use in a plasma processing chamber is provided. A disk shaped component body has a plasma facing surface, wherein the disk shaped component body comprises a spark plasma sintered body comprising a non-oxide material containing silicon consisting essentially of a non-oxide silicon containing material and at least one of a B or B₄C dopant. A plurality of inlet holes is machined into the plasma facing surface of the disk shaped component body

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2A-FIG. 2D show an embodiment of a method for fabricating an edge ring component for use in a plasma processing chamber. FIG. 2A is a cross-sectional view of a silicon carbide powder placed in a mold. FIG. 2B is a cross-sectional view of an edge ring formed after spark plasma sintering (SPS) the silicon carbide powder. FIG. 2C is a side view of the edge ring removed from the mold. FIG. 2D is a side view of the edge ring after further processing to form an edge ring component for use in a plasma processing chamber.

FIG. 3A-FIG. 3F show an embodiment of a method for fabricating a gas distribution plate component for use in a plasma processing chamber. FIG. 3A is a cross-sectional view of a silicon carbide powder placed in a mold. FIG. 3B is a cross-sectional view of a gas distribution plate formed after spark plasma sintering (SPS) the silicon carbide powder. FIG. 3C is a plan view of the gas distribution plate removed from the mold. FIG. 3D is a side view of the gas distribution plate of FIG. 3C. FIG. 3E is a plan view of the gas distribution plate after further processing to form a gas distribution plate component for use in a plasma processing chamber.

FIG. 3F is a side view of the gas distribution plate component of FIG. 3E.

FIG. 4 is a schematic view of a plasma processing chamber according to an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

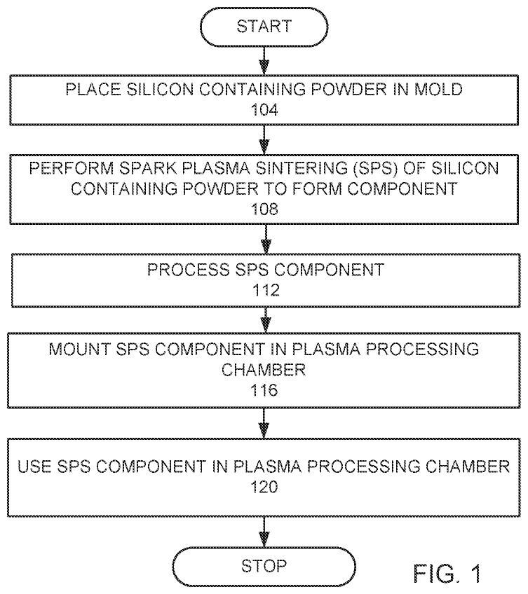

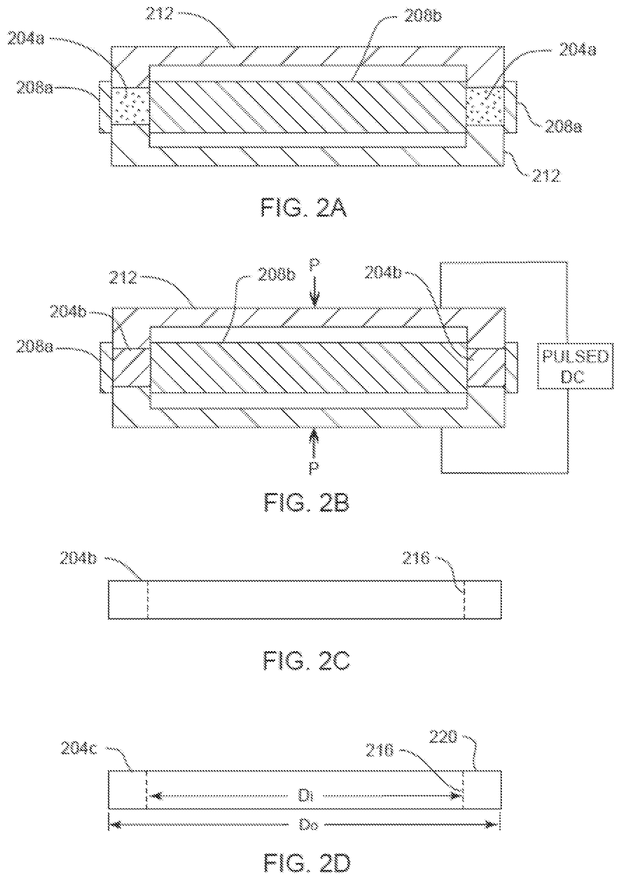

To facilitate understanding, FIG. 1 is a high level flow chart of an embodiment of a method of fabricating a component for a plasma processing chamber. A non-oxide silicon containing powder composition is placed in a mold (step 104). In this embodiment, the non-oxide silicon containing powder comprises a silicon carbide powder and one or more sintering additives comprising at least one of a boron (B) or boron carbide (B₄C) dopant to aid in the fabrication process. In one embodiment, the atomic fraction of boron to silicon is in the range of 0.01% to 30%. In other embodiments, the atomic fraction of boron to silicon is in the range of 1% to 20%. In other embodiments, the atomic fraction of boron to silicon is in the range of 10% to 20%. In other embodiments, the atomic fraction of boron to silicon is greater than 10%. In some embodiments, the non-oxide material containing silicon consists essentially of SiC powder and at least one of B or B₄C. In some embodiments, the non-oxide material containing silicon consists essentially of SiC powder and B₄C. FIG. 2A shows a cross-section view of a non-oxide material containing silicon 204a (having at least one of a boron (B) or boron carbide (B₄C) dopant) placed in an annular recess or cavity of a mold 208 for fabricating a component of a plasma processing chamber. The mold 208 comprises an outer mold ring 208a and an inner mold 208b. In this example, the component is an edge ring for use in a plasma processing chamber. The mold 208 is configured for processing the non-oxide material containing silicon 204a according to a Spark Plasma Sintering (SPS) process, and in one embodiment includes a pair of conductive pads 212 that enclose upper and lower ends of the mold 208 cavity and act as pistons or punches to apply a compressive force P on the non-oxide material containing silicon 204a within the mold 208.

Referring back to FIG. 1, the non-oxide material containing silicon 204a is then subjected to Spark Plasma Sintering (SPS) to form silicon or silicon carbide and B or B₄C dopant composition into a Spark Plasma Sintered part or component (step 108). In the exemplary embodiment illustrated in the cross-section view of FIG. 2B, the non-oxide material containing silicon 204a is then subjected to SPS to form the silicon carbide powder and B or B₄C dopant composition into a Spark Plasma Sintered formed edge ring 204b.

As compared to conventional sintering processes, the SPS process (also referred to as pulsed electric current sintering (PECS), Field-Assisted Sintering (FAST) or Plasma Pressure Compaction (P2C)) involves contemporaneous use of pressure and high-intensity, low-voltage (e.g. 5-12 V), pulsed current to dramatically reduce processing/heating times (e.g. 5-10 minutes (min) instead of several hours) and yield high-density components. In one embodiment, a pulsed DC current is transmitted to the deposited the non-oxide material containing silicon 204a using conductive pads 212 as electrodes, while pressure (e.g. between 10 megapascals (MPa) up to 500 MPa or more) is simultaneously axially applied to the non-oxide material containing silicon 204a via reciprocation of the conductive pads 212 under mono-axial mechanical force. A “mono-axial force” is herein defined to mean a force applied along a single axis or direction creating mono-axial compression. The mold 208 and non-oxide material containing silicon 204a are generally placed under vacuum during at least a portion of the process. Pulsed-current patterns (ON:OFF), typically in milliseconds, enable high heating rates (up to 1000° C./min or more), and rapid cooling/quenching rates of (up to 200° C./min or more) for heating the non-oxide material containing silicon 204a to temperatures ranging from under 1000° C. to 2500° C. In one embodiment, the ON-OFF DC pulse-energizing of the SPS process generates one or more of the following in the SiC composition: 1) spark plasma, 2) spark impact pressure, 3) Joule heating, and 4) an electrical field diffusion effect.

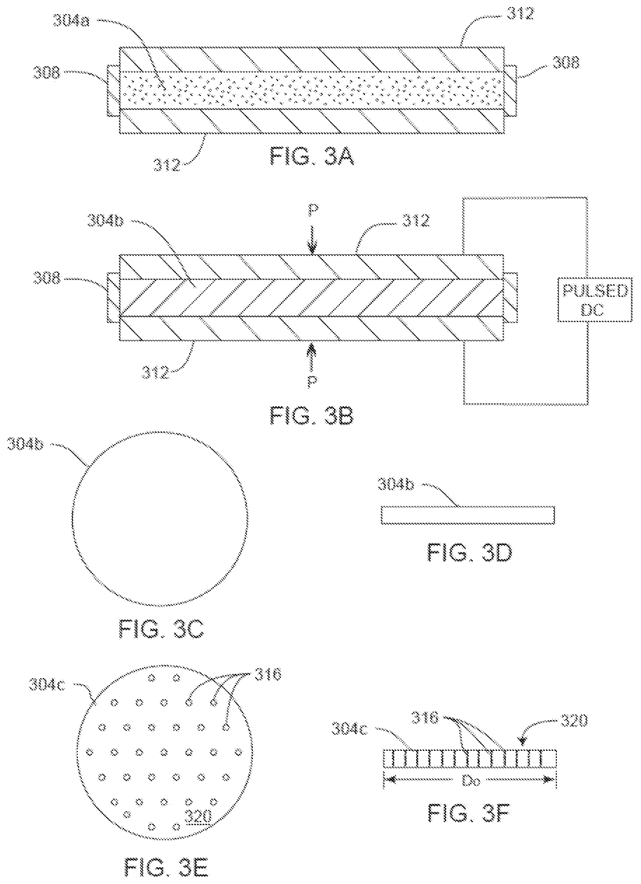

It is appreciated that the scale and geometry of the mold 208, conductive pads 212, non-oxide material containing silicon 204a, and SPS-formed edge ring 204b provided in the schematic views of FIGS. 2A and 2B (as well elements detailed in FIG. 3A and FIG. 3B) are provided for illustrative purposes only, and such elements may vary as to size, scale, shape, and form with respect to each other. Furthermore, it is appreciated that mold 208 and conductive pads 212 may be provided as part of an SPS apparatus (not shown) comprising one or more of the following: vertical single-axis pressurization mechanism, cooled vacuum chamber, atmosphere controls, vacuum exhaust unit, sintering DC pulse generator and a SPS controller, among other elements.

In one embodiment of an SPS process, provided for exemplary purposes only, sintering of the composition of silicon carbide powder and sintering additives is conducted under vacuum (6<P(Pa)<14) while being simultaneously subjected to a pulsed current. The SPS thermal treatment may be implemented as follows: 1) a degassing treatment performed for a period between 3 min to 10 min, and preferably with the non-oxide material containing silicon 204a subjected to 3 min under limited applied load (e.g. between 10 MPa and 20 MPa) and 2 min under increasing load up to 40 MPa to 100 MPa, and 2) heating up to between 1850° C. and 1950° C. at 100° C. min⁻¹ under an applied load between 40 MPa to 100 MPa and a soaking time of 5 min at maximum temperature then cooling down to room temperature. It is appreciated that one or more of the SPS process parameters, including composition constituent ratios and particulate size, pressures, temperatures, treatment periods, and current pulse sequences, may be varied as appropriate to optimize the SPS process.

Referring to the side view of FIG. 2C, the SPS-formed edge ring 204b is removed from the mold 208 as an SPS-formed component, and in this embodiment a SPS-formed edge ring 204b having a central channel 216. The SPS-formed edge ring 204b forms a ring shaped spark plasma sintered body with a plasma facing surface. The SPS-formed component is characterized by a high degree of densification, reaching nearly 100% (e.g. 99% or greater relative density, and preferably between 99.5% and 100% relative density) with isotropic properties having reduced diffusion between grains and minimized or prevented grain growth. The ring shaped spark plasma sintered body comprises a non-oxide material containing silicon that consists essentially of a non-oxide silicon containing material and at least one of a B or B₄C dopant. The non-oxide silicon containing material may be silicon or a non-oxide silicon compound, such as silicon carbide (SiC). The non-oxide silicon containing powder may be at least one of silicon powder or a non-oxide silicon compound powder, such as a silicon carbide powder.

Following the SPS process, the component may be further processed (step 112, e.g., polishing, machining, or like process) to specifically adapt the component for use in a plasma processing chamber. It is appreciated that the mold and/or SPS process may be structured so that the further processing in step 112 is not required. The SPS-formed edge ring 204b may be formed as a near net shape part (NNS). A NNS part requires subsequent machining removing less that 20% of the volume of the NNS part.

Referring to the side view of FIG. 2D, the Spark Plasma Sintered formed edge ring 204b is further processed to form the processed edge ring 204c. For example, one or more surfaces 220 (e.g. inner surface and diameter Dᵢ of central channel 216, outer circumferential surface having outer diameter Dₒ, and/or top or bottom surfaces) of the SPS-formed edge ring 204b may be polished, honed, machined, etc. to form an edge ring 204c specifically adapted for use in a plasma processing chamber.

The processed SPS body is then mounted or otherwise installed in a plasma processing chamber (step 116), wherein the SPS component is used in the plasma processing chamber (step 120) for performing plasma processing of one or more wafers or substrates. During plasma processing, one or more surfaces of the SPS component is exposed to plasma and/or dielectric-etch processes.

The plasma processing performed by the plasma processing chamber may include one or more processes of etching, depositing, passivating, or another plasma process. The plasma processing may also be performed in combination with non-plasma processing. Such processes may expose the various components of the plasma processing chamber to plasmas containing halogen and/or oxygen that result in erosion or degradation of the part.

The SPS process illustrated in FIG. 1 is particularly useful for fabricating consumable dielectric plasma processing chamber components. More specifically, the processes illustrated in FIG. 1 and FIG. 2A through FIG. 2D are particularly suited for forming and/or conditioning one or more components of a plasma processing chamber to inhibit or minimize consumption of the component via plasma and etching processes inherent in the plasma processing chamber. Such components include pinnacles and electrostatic chucks (ESCs), in addition to high flow liners, gas distribution plates, and edge rings, among other parts in the plasma processing chamber that may be exposed to plasma or energetic ions.

Accordingly, FIG. 3A through FIG. 3F illustrate another embodiment of a method of fabricating a plasma processing component, and in particular a chamber gas distribution plate, using the SPS process in accordance with the present description. FIG. 3A shows a cross-section view of a SiC composition 304a (having at least one of a boron (B) or boron carbide (B₄C) dopant) placed in a recess or cavity of mold 308 for fabricating a gas distribution plate of a plasma processing chamber. The mold 308 is configured for processing the SiC composition 304a according to the SPS process. One embodiment includes a pair of conductive pads 312 that enclose upper and lower ends of the mold 308 cavity and act as pistons or punches to apply a compressive force on the SiC composition 304a within the mold 308.

Referring to the cross-section view of FIG. 3B, the SiC composition 304a is then subjected to SPS to form the B/B₄C-doped silicon carbide powder composition into a Spark Plasma Sintered formed disk 304b (step 108) via simultaneous application of compressive force P and pulsed current applied at conductive pads 312 according to the SPS process detailed above with respect to FIG. 2B.

Referring to the respective plan and side views of FIG. 3C and FIG. 3D, the SPS-formed disk 304b is removed from the mold 308 and is characterized by a high degree of densification, reaching nearly 100% with isotropic properties having reduced diffusion between grains and minimized or prevented grain growth. In various embodiments, the densification provides a densification of 99% or greater relative density, and preferably between 99.5% and 100% relative density. The formed disk 304b is a disk shaped component body.

Referring to the respective plan and side views of FIG. 3E and FIG. 3F, the SPS-formed disk 304b is further processed to form a processed gas distribution plate 304c. For example, a plurality of gas inlet holes 316 may be drilled into the formed disk 304b to form a gas distribution plate 304c. In the illustration shown in FIG. 3E and FIG. 3F, the holes 316 are not drawn to scale in order to better illustrate the embodiment. In different embodiments, the holes 316 may have various spacing and/or geometric patterns, e.g., circular, grid, etc. Furthermore, one or more surfaces (e.g. outer circumferential surface having diameter Dₒ, and/or top or bottom surfaces) of the SPS-formed disk 304b may be polished, honed, machined, etc. to form a gas distribution plate 304c specifically adapted from use in a plasma processing chamber. The gas distribution plate 304 is adapted to receive gas from a gas source and provide the gas into a plasma processing chamber. In this embodiment, one of the polished surfaces is a plasma facing surface 320. The holes 316 are drilled into the plasma facing surface 320. The plasma facing surface 320 is a surface facing or exposed to a plasma when used in a plasma processing chamber. When the plasma facing surface 320 is exposed to plasma or a remote plasma, the plasma facing surface may also be called a plasma exposed surface.

The plasma processing components (e.g. edge ring 204c, gas distribution plate 304c) generated from the SPS process are resistant to erosion from exposure to plasma, such that the component is either no longer a consumable, or substantially inhibits consumption to limit or obviate the need to change or replace the component due to erosion. Being more etch resistant, components fabricated and installed via the process illustrated in FIG. 1 also minimize/prevent the generation of impurities during plasma processing. The SPS process detailed in FIG. 1 is also particularly amenable for fabricating large parts, e.g. forming edge rings 204c and gas distribution plates 304c having outer diameters (Dₒ) of 14 inches (35.56 centimeters) or greater.

The integrity of the dielectric components discussed above with respect to plasma processing chambers is crucial to maintain both electrical standoff, plasma erosion resistance, and chemical resistance. The SPS-formed components as detailed in the present description provide significant advantages over dielectric coated parts, as dielectric coatings that are too thick are more susceptible to cracking, and thinner dielectric coatings do not provide sufficient insulation to prevent damage caused by the voltage used by the plasma processing chamber.

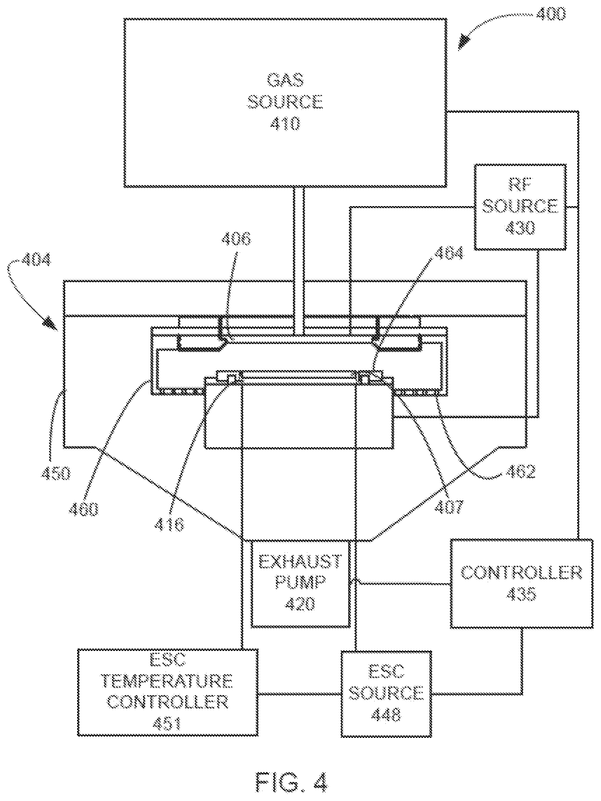

Referring to the schematic system view of FIG. 4, one or more processed and SPS-formed components may be mounted or otherwise installed for use in a plasma processing chamber 400 for processing a wafer or substrate 407. An example of such a plasma processing chamber is the Flex® etch system manufactured by Lam Research Corporation of Fremont, CA. The plasma processing chamber in this embodiment is a CCP (capacitively coupled plasma) reactor.

In one exemplary configuration, the one or more processed and SPS-formed components comprise consumable plasma processing chamber components such as an edge ring, gas distribution plate, high flow liner, etc. In some embodiments, the plasma processing chamber 400 comprises a gas distribution plate 406, also referred to as a “showerhead” for providing a gas inlet within a plasma processing chamber 404. The gas distribution plate 406 may be mounted in a plasma processing chamber 404 along with an electrostatic chuck (ESC) 416, all being enclosed by a chamber wall 450. Within the plasma processing chamber 404, a substrate or wafer 407 is positioned on top of the ESC 416 that acts as a wafer support to support the substrate 407. The ESC 416 may provide a bias from an ESC power source 448. A gas source 410 is connected to the plasma processing chamber 404 through the gas distribution plate 406. An ESC temperature controller 451 is connected to the ESC 416 and provides temperature control of the ESC 416. A radio frequency (RF) power source 430 provides RF power to the ESC 416 and an upper electrode. In this embodiment, the upper electrode is the gas distribution plate 406. In a preferred embodiment, 13.56 megahertz (MHz), 2 MHz, 60 MHz, and/or optionally, 27 MHz power sources make up the RF power source 430 and the ESC power source 448. A controller 435 is controllably connected to the RF power source 430, the ESC power source 448, an exhaust pump 420, and the gas source 410.

A high flow liner 460 is a liner within the plasma processing chamber 404, and may also be formed, installed, and used in accordance with the steps illustrated in FIG. 1. The high flow liner 460 confines gas from the gas source and has slots 462. The slots 462 maintain a controlled flow of gas to pass from the gas source 410 to the exhaust pump 420.

An edge ring 464 surrounds the substrate 407. The plasma processing chamber 404 uses the edge ring 464 to plasma process the substrate 407. It is desirable that the top surface of the edge ring 464 be level with a top surface of the substrate 407. Therefore, the use of an SPS-formed edge ring 204c as edge ring 464 obviates various mechanisms that are typically provided to move the edge ring as the edge ring is consumed in order to keep the top surface of the edge ring even with the top surface of the substrate. In addition, once an edge ring is sufficiently consumed, the edge ring must be replaced, causing downtime for the plasma processing chamber. In other embodiments, such components may be placed in locations shielded from plasma. Ceramic edge rings have a low coefficient of thermal expansion and good electrical and thermal conductivity.

In other embodiments, the components may be parts of other types of plasma processing chambers such as a TCP (transformer coupled plasma) reactor, a bevel plasma processing chambers or like device. Examples of components of plasma processing chambers that may be provided in various embodiments are confinement rings, plasma exclusion rings, edge rings, the electrostatic chuck, ground rings, chamber liners, door liners, the pinnacle, a showerhead, a dielectric power window, gas injectors, edge rings, ceramic transfer arms, or other components.

In various embodiments, the non-oxide silicon containing powder comprises silicon powder with a B₄C dopant. In some embodiments, the non-oxide silicon containing powder consists essentially of silicon powder with a B₄C dopant. In one embodiment, the atomic fraction of boron to silicon is in the range of 0.01% to 30%. In other embodiments, the atomic fraction of boron to silicon is in the range of 1% to 20%. In other embodiments, the atomic fraction of boron to silicon is in the range of 10% to 20%.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for making a component for use in a plasma processing chamber, comprising:
placing a non-oxide silicon containing powder composition in a mold, wherein the non-oxide silicon containing powder composition consists essentially of a non-oxide silicon containing powder and at least one of a B or B₄C dopant;
subjecting the non-oxide silicon containing powder composition to spark plasma sintering (SPS) to form a spark plasma sintered component; and
machining the spark plasma sintered component into a plasma processing chamber component.

2. The method, as recited in claim 1, wherein an atomic fraction of boron to silicon in the non-oxide silicon containing powder composition is in a range of 0.10% to 20%.

3. The method, as recited in claim 1, wherein the plasma processing chamber component is at least one of a gas distribution plate, edge ring, or liner of the plasma processing chamber.

4. The method, as recited in claim 1, wherein the non-oxide silicon containing powder consists essentially of silicon carbide powder and at least one of a B or B₄C dopant.

5. The method, as recited in claim 4, wherein the at least one of a B or B₄C dopant is a B₄C dopant.

6. The method, as recited in claim 1, wherein the non-oxide silicon containing powder consists essentially of silicon powder and a B₄C dopant.

7. A component for use in a plasma processing chamber, the component made by the method of claim 1.

8. An apparatus for processing a wafer, comprising:
a plasma processing chamber;
a wafer support for supporting a wafer within the plasma processing chamber;
a gas source for providing gas to the plasma processing chamber; and
a component, comprising a spark plasma sintered body comprising a non-oxide material containing silicon consisting essentially of a non-oxide silicon containing material and at least one of a B or B₄C dopant.

9. The apparatus, as recited in claim 8, wherein an atomic fraction of boron to silicon in the component is in a range of 10% to 20%.

10. The apparatus, as recited in claim 8, wherein the component is at least one of a gas distribution plate, edge ring, or liner of the plasma processing chamber.

11. The apparatus, as recited in claim 8, wherein the non-oxide silicon containing material consists essentially of silicon carbide.

12. The apparatus, as recited in claim 11, wherein the at least one of a B or B₄C dopant is a B₄C dopant.

13. The apparatus, as recited in claim 8, wherein the non-oxide silicon containing material consists essentially of silicon.

14. An edge ring for use in a plasma processing chamber, comprising a ring shaped body with a plasma facing surface, the ring shaped body, comprising a spark plasma sintered body comprising a non-oxide material containing silicon consisting essentially of a non-oxide silicon containing material and at least one of a B or B₄C dopant.

15. The edge ring, as recited in claim 14, wherein the non-oxide silicon containing material consists essentially of silicon carbide.

16. The edge ring, as recited in claim 15, wherein the at least one of a B or B₄C dopant is a B₄C dopant.

17. The edge ring, as recited in claim 14, wherein the non-oxide silicon containing material consists essentially of silicon.

18. A showerhead for use in a plasma processing chamber, comprising:
a disk shaped component body with a plasma facing surface, wherein the disk shaped component body comprises a spark plasma sintered body comprising a non-oxide material containing silicon consisting essentially of a non-oxide silicon containing material and at least one of a B or B₄C dopant; and
a plurality of inlet holes machined into the plasma facing surface of the disk shaped component body.

19. The showerhead, as recited in claim 18, wherein the non-oxide silicon containing material consists essentially of silicon carbide.

20. The showerhead, as recited in claim 19, wherein the at least one of a B or B₄C dopant is a B₄C dopant.

21. The showerhead, as recited in claim 18, wherein the non-oxide silicon containing material consists essentially of silicon.
